(19) United States
(12) Patent Application Publication
(10) Pub. No.: US 2023/0093241 A1
(43) Pub. Date: Mar. 23, 2023

(54) ELEMENT ARRAY PRESSURIZING DEVICE, MANUFACTURING DEVICE, AND MANUFACTURING METHOD

(71) Applicant: TDK CORPORATION, Tokyo (JP)

(72) Inventors: Hiroshi KOIZUMI, Tokyo (JP); Yasuo KATO, Tokyo (JP); Makoto YAMASHITA, Tokyo (JP); Mitsuyoshi MAKIDA, Tokyo (JP); Ryo SHINDO, Tokyo (JP); Osamu SHINDO, Tokyo (JP); Hiroshi IIZUKA, Tokyo (JP); Seijiro SUNAGA, Tokyo (JP); Toshinobu MIYAGOSHI, Tokyo (JP)

(73) Assignee: TDK CORPORATION, Tokyo (JP)

(21) Appl. No.: 17/909,080

(22) PCT Filed: Mar. 4, 2021
(86) PCT No.: PCT/JP2021/008466

§ 371 Date: Sep. 2, 2022

(30) Foreign Application Priority Data
Mar. 4, 2020 (JP) 2020-036723
Mar. 4, 2020 (JP) 2020-036736

(51) Int. Cl. H01L 33/00

(52) U.S. Cl. CPC H01L 33/005

(57) ABSTRACT

An element array pressurizing device has a pressurizing plate having a pressurizing unit that pressurizes an element array comprising a plurality of elements disposed on a mounting substrate. The pressurizing unit has a plate-shaped hard material for which a surface precision is higher than that of a surface of the pressurizing plate.

### TECHNICAL FIELD

The present invention relates to an element array pressing device which applies pressure to an element array including a plurality of elements placed on a mounting substrate, and also the present invention relates to a manufacturing apparatus and a method of producing the element array.

### BACKGROUND

As a method of producing an element array including a plurality of elements (for example, a light emitting element, and the like), for example, the below described method is known. That is, a method which places the plurality of elements in a form of array on the mounting substrate where conductive bonding materials are provided such as ACF (Anisotropic Conductive File), ACP (Anisotropic Conductive Paste), and the like, or eutectic metals such as Sn, Pb, Ag, Au, Bi, In, Ca, Cu, Ge, and the like. Then, the plurality of elements placed in a form of array (element array) is pressed using a press plate made of metal such as stainless steel and the like, and the element array is mounted on the mounting substrate via the conductive bonding material. Thereby, the element array is mounted on the mounting substrate.

When the element array is pressed using the press plate, as in case of the invention disclosed in the Patent Document 1, a resilient layer with fluidity is placed between the press plate in order to press each element of the plurality of elements further evenly.

However, even by the invention disclosed in the Patent Document 1, it is difficult to sufficiently avoid uneven pressing to each element of the plurality of elements (unevenness of the applied pressure), which still had a risk of causing a mounting malfunction.

[Patent Document 1] JP Patent Application Laid Open No.2004-296746

### SUMMARY

The present invention is achieved in view of such circumstances, and the object is to provide an element array pressing device, an element array manufacturing apparatus, and an element array producing method capable of stably producing an element array on the mounting substrate.

### DETAILED DESCRIPTION

In order to achieve the above object, an element array pressing device according to the first aspect of the present invention includes a press plate including a pressing part applying pressure to an element array having a plurality of elements provided on a mounting substrate, wherein
the pressing part includes a hard member in a plate shape having a surface with a higher surface flatness than a surface of the press plate.

In the element array pressing device according to the present invention, the pressing part includes the hard member in a plate shape having a surface with a higher surface flatness than the surface of the press plate. Therefore, when pressure is applied using the pressing plate, the element array having the plurality of elements placed on the mounting substrate can be pressed via the hard member. The surface flatness (such as evenness, smoothness, and so on) of the hard member is higher compared to the surface flatness of the press plate, thus contact between the surface of the element array and the like and a pressing face (a surface contacting the element array) of the pressing part (the hard member is enhanced, and pressure can be applied evenly to each element of the plurality of element placed on the mounting substrate. Therefore, the element array pressing device according to the present invention can prevent mounting malfunction, and the element array can be stably produced on the mounting substrate.

The hard member may be provided on the surface of the press plate. By taking such configuration, even when the surface flatness of the press plate is not necessarily good, the hard member can directly absorb this. Hence, the mounting malfunction is effectively prevented, and the element array can be stably formed on the mounting substrate.

Preferably, the pressing part may include a resilient member in a plate shape, and the resilient member is provided on the surface of the hard member, In this case, when the pressure is applied using the press plate, the plurality of elements placed on the mounting substrate can be pressed via the resilient member. The resilient member deforms moderately along the surface shape of the element array and the like; hence pressure can be applied further evenly to the plurality of elements placed on the mounting substrate.

The pressing part may include a resilient member in a plate shape, the resilient member may be provided on the surface of the press plate, and the hard member may be provided on a surface of the resilient member. In this case, the resilient part deforms moderately, and the surface of the element array and the like and the surface of the hard member constituting the contacting face against the element array and the like easily become parallel to each other. Hence, pressure can be applied further evenly to the plurality of elements constituting the element array.

Preferably, the hard member may include ones or more hard members and the resilient member may include one or more resilient members, and the one or more hard members and the one or more resilient members may be stacked in an alternating manner on the surface of the press plate. In this case, the press plate includes the hard member and the resilient member, the aforementioned effects can be both attained, and the plurality of elements placed on the mounting substrate can he pressed more evenly.

Preferably, a first water repelling layer, obtained by carrying out a water repellant treatment, may be formed on the surface of the hard member. By constituting as such, when the element array formed on the mounting substrate is pressed via the surface of the hard member, the first water repelling layer allows to prevent the element from adhering to the surface of the hard member, hence the mounting malfunction can be effectively prevented. Also, in case the plurality of elements is mounted on the mounting substrate using the conductive bonding material, even if the conductive bonding material contacts with the pressing part when the pressing part is pressed, the first water repelling layer prevents the conductive bonding material from adhering to the pressing part. Hence, damage to the press plate can be prevented which is caused when the conductive bonding material adheres to the pressing part.

Preferably, a second water repelling layer, obtained by carrying out a water repellant treatment, may be formed on a surface of a resilient member. By taking such configuration, when the element array formed on the mounting substrate is pressed via the surface of the resilient member, the second water repelling layer prevents the element from adhering to the surface of the resilient member, hence the mounting malfunction can be effectively prevented. Also, in case the plurality of elements is mounted on the mounting substrate using the conductive bonding material, even if the conductive bonding material contacts with the pressing part when the pressing part is pressed, the second water repelling layer allows to prevent the conductive bonding material from adhering to the pressing part.

Preferably, a thickness of the first water repelling layer may be thinner than a thickness of the hard member, and a thickness of a second water repelling layer may be thinner than a thickness of a resilient member. Such configuration effectively prevents the element from adhering to the surface of the hard member or resilient member.

Preferably, the hard member may be provided in a detachable manner to the press plate. By taking such configuration, the hard member and the like provided to the press plate can be easily exchanged to other one. Also, the hard member provided to the press plate can be changed to appropriate hard member depending on a type of the element, a shape of the mounting substrate, and so on.

Preferably, the hard member may be fixed to the press plate with a clamping member. By taking such configuration, the hard member can be fixed to the press plate with sufficient fixing strength using the clamping member. Also, the hard member can be easily detached from the press plate, hence the hard member can be exchanged easily.

In order to achieve the above object, a manufacturing apparatus of the element array according to the present invention includes the above-mentioned element array pressing device. By mounting the element array on the mounting substrate using the element array pressing device mentioned in above, pressure can be evenly applied to the plurality of elements placed on the mounting substrate, thus prevents the mounting malfunction, and the element array can be stably formed on the mounting substrate.

The element array manufacturing apparatus may further include,
a mounting table on which the mounting substrate is placed,
a supply table on which a supply substrate having a plurality of elements is placed, and
a transferring machine which moves to the supply table and picks up the plurality of elements from the supply substrate and also moves to the mounting table and transfers the plurality of elements picked up from the supply substrate to the mounting substrate; in which
the press plate applies pressure to the element array having the plurality of elements transferred to the mounting substrate with the transferring machine.

By taking such configuration, during a so-called mass transfer, even when the plurality of elements is transferred from the supply substrate to the mounting substrate all at once, and the element array having these elements is pressed using the press plate, the element array can be stably formed on the mounting substrate, and a yield during the production can be improved.

In order to achieve the above-mentioned object, a method of producing an element array includes steps of
preparing a mounting substrate on which a plurality of elements is placed, and
applying pressure to the plurality of elements placed on the mounting substrate using a pressing device provided with a hard member in a plate shape having a surface with a higher surface flatness than a surface of a press plate.

Regarding the method of producing an element array according to the present invention, the plurality of elements placed on the mounting substrate is pressed using a pressing device provided with a hard member in a plate shape having a surface with a higher surface flatness than the surface of the press plate. Hence, the contact between the surface of the plurality of elements and the like and the pressing face (the contacting face against the element array) of the pressing part (hard member) is enhanced (becomes parallel to each other), thus the plurality of elements placed on the mounting substrate can be pressed evenly. Therefore, by using to the method of producing the element array according to the present invention, the mounting malfunction can be prevented, and the element array can be stably formed on the mounting substrate.

Preferably, the plurality of elements may be connecting to the mounting substrate by pressing the plurality of elements towards a conductive bonding material provided on the mounting substrate. By taking such configuration, the plurality of elements can be mounted on the mounting substrate using the conductive bonding material such as ACF (Anisotropic Conductive File), ACP (Anisotropic Conductive Paste), and the like. Thus, the element array can be formed easily on the mounting substrate.

In order to achieve the above-mentioned object, the element array pressing device according to the second aspect of the present invention includes a press plate including a pressing part which applies pressure to an element array having a plurality of elements placed on the mounting substrate, wherein
the pressing part includes a resilient member in a plate shape, and
a thickness of the resilient member is within a range of 0.5 to 2.0 times of a thickness of an element of the plurality of elements.

In the pressing device according to the present invention, the pressing part includes the resilient member in a plate shape. Thus, when pressure is applied using the press plate, the element array having the plurality of elements placed on the mounting substrate can be pressed via the resilient member.

Particularly, in the pressing device according to the present invention, a thickness of the resilient member is within a range of 0.5 times to 2 times of the thickness of the element. When the thickness of the resilient member compared to the thickness of the element is set within said range, an appropriate thickness is given to the resilient member. Thus, the resilient member can easily deform moderately following the surface shape of the element array and the like, and pressure can be thoroughly applied to the entire element array via the resilient member. Also, since the resilient member has an appropriate hardness, a sufficient pressing force can be applied to the element via the resilient member. Therefore, pressure can be evenly applied to the plurality of elements placed on the mounting substrate.

Also, pressure is generated along with the deformation of the resilient member, however, when the thickness of the resilient member compared to the thickness of the element is set within the above-mentioned range, such pressure will not have significant impact on the pressing force of the press plate. Therefore, uneven distribution of the pressing force of the press plate is prevented when pressure is applied using the press plate, and pressure can be evenly applied to the plurality of elements placed on the mounting substrate. Thus, the element array pressing device according to the present invention can prevent the mounting malfunction, and the element array can be formed stably on the mounting substrate.

The resilient member may be provided on a surface of the press plate. By taking such configuration, when the press plate is heated while applying pressure using the press plate, the heat from the press plate can easily transferred to the resilient member, thus the plurality of elements can be securely mounted on the mounting substrate, for example, by using the conductive bonding material provided on the mounting substrate.

The pressing part may include a hard member in a plate shape having a surface with a higher surface flatness than a surface of the press plate, the hard member may be provided on a surface of the resilient member, and another resilient member may be provided on the surface of the hard member. The surface flatness (such as evenness, smoothness, and so on) of the hard member is higher than the surface flatness (such as evenness, smoothness, and so on) of the press plate, hence by providing the hard member between the resilient members, the resilient member at outer side which constitutes the contacting face against the element array and the like can be placed approximately parallel to a horizontal plane. Thus, the contact between the surface of the element array and the pressing face (the contacting face against the element array) of the pressing part (the resilient member) is enhanced (becomes parallel to each other), thus the plurality of elements placed on the mounting substrate can be pressed evenly. Therefore, the mounting malfunction is effectively prevented, and the element array can be stably formed on the mounting substrate.

Also, as the resilient member provided on the surface of the press plate deforms, the surface of the element array easily becomes parallel to the surface of the resilient member at the outer side constituting the contacting face against the element array, hence the plurality of elements constituting the element array can be pressed more evenly.

The pressing part includes the hard member in a plate shape having a surface with a higher surface flatness than the surface of the press plate. The hard member is provided on the surface of the press plate, and the resilient member is provided on the surface of the hard member. By taking such configuration, even when the press plate does not have sufficient surface flatness, this can be directly absorbed by the hard member. Thus, the resilient member constituting the contacting face against the element array can be placed approximately parallel to the horizontal plane, and the contact between the surface of the plurality of elements and the like and the pressing face (the contacting face against the element array) of the pressing part (the resilient member) is enhanced (becomes parallel to each other). Therefore, the pressure can be applied evenly to the plurality of elements placed on the mounting substrate, thus the mounting malfunction can be effectively prevented, and the element array can be stably formed on the mounting substrate.

Preferably, the hard member may include one or more hard members and the resilient member may include one or more resilient members, and
the one or more hard members and the one or more resilient members may be stacked in an alternating manner on the surface of the press plate. By taking such configuration, the aforementioned effect is enhanced, which can be obtained by providing the hard member and the resilient member to the press plate, thus the plurality of elements placed on the mounting substrate can be pressed more evenly.

Preferably, a water repelling layer, obtained by carrying out a water repellant treatment, may be formed on the surface of the resilient member. By taking such configuration, when the element array formed on the mounting substrate is pressed, adhesion of the element to the surface of the resilient member can be prevented, and the mounting malfunction can be effectively prevented. Also, in case the plurality of elements is mounted on the mounting substrate using the conductive bonding material, when pressure is applied using the press plate, even if the pressing part contacts with the conductive bonding material, the water repelling layer can prevent the conductive bonding material from adhering to the pressing part. Thus, damage to the pressing plate which is caused as the conductive bonding material adheres to the pressing part can be prevented.

Preferably, a thickness of the water repelling layer may be thinner than a thickness of the resilient member. By taking such configuration, this effectively prevents the element from adhering to the surface of the resilient member.

The thickness of the element may be 50 μm or less. Even in case the element array having such small elements is pressed, as the resilient member moderately deforms following the surface shape of the element array and the like, the plurality of elements constituting the element array can be pressed evenly.

In order to achieve the above object, the element array manufacturing apparatus includes any one of the element array pressing devices mentioned in above. By mounting the element array on the mounting substrate using any one of the above-mentioned pressing devices, the plurality of elements placed on the mounting substrate can be pressed evenly, thus prevents the mounting malfunction, and the element array can be stably formed on the mounting substrate.

The element array manufacturing apparatus may include,
a mounting table on which a mounting substrate is placed,
a supply table on which a supply substrate having a plurality of elements is placed, and
a transferring machine which moves to the supply table and picks up the plurality of elements from the supply substrate and also moves to the mounting table and transfers the plurality of elements picked up from the supply table to the mounting substrate, in which
the press plate applies pressure to the element array having the plurality of elements transferred to the mounting substrate with the transferring machine.

By taking such configuration, during a so-called mass transfer, even when the plurality of elements is transferred from the supply substrate to the mounting substrate all at once, and the element array having these elements is pressed using the press plate, the element array can be stably formed on the mounting substrate, and a yield during the production can be improved.

In order to achieve the above-mentioned object, a method of producing the element array according to the present invention includes steps of
preparing a mounting substrate on which a plurality of elements is placed,
applying pressure to the plurality of elements placed on the mounting substrate with a pressing device provided with a resilient member in a plate shape having a thickness of 0.5 to 2.0 times of a thickness of an element of the plurality of elements.

In an element array mounting method, the plurality of element placed on the mounting substrate is pressed using the pressing device provided with the resilient member in a form of a plate having a thickness of 0.5 to 2.0 times of the thickness of the element. Thus, the resilient member moderately deforms following the surface shape of the element array and the like, thus a sufficient pressing force can be thoroughly applied to the entire element array via the resilient member. Also, uneven distribution of the pressing force of the press plate is prevented, and the plurality of elements placed on the mounting substrate can be pressed evenly. Thus, according to the element array mounting method of the present invention, the mounting malfunction is prevented, and the element array can be stably formed on the mounting substrate.

Preferably, the plurality of elements is connected to the mounting substrate by pressing the plurality of elements towards the conductive bonding material provided on the mounting substrate. Thus, the plurality of elements can be mounted on the mounting substrate using the conductive bonding material such as ACF (Anisotropic Conductive File), ACP (Anisotropic Conductive Paste), and the like; hence, the element array can be easily formed on the mounting substrate.

### BRIEF DESCRIPTION OF THE SEVERAL VIEWS OF THE DRAWINGS

FIG. 1 is a schematic side view showing a pressing device according to the first embodiment of the present invention.

FIG. 2 is a block diagram showing a functional constitution of an element array manufacturing apparatus including the pressing device shown in FIG. 1.

FIG. 3A is a cross section view showing a step of transferring an element from a supply substrate to a mounting substrate by a mass transfer.

FIG. 3B is a cross section view of a subsequent step after the step shown in FIG. 3A.

FIG. 3C is a cross section view of a subsequent step after the step shown in FIG. 3B.

FIG. 4 is a schematic side view showing a pressing device according to the second embodiment of the present invention.

FIG. 5 is a schematic side view showing a pressing device according to the third embodiment of the present invention.

FIG. 6 is a schematic side view showing a pressing device according to the fourth embodiment of the present invention.

FIG. 7 is a schematic side view showing a pressing device according to the fifth embodiment of the present invention.

FIG. 8 is a schematic side view showing a pressing device according to the sixth embodiment of the present invention.

FIG. 9 is a schematic side view showing a pressing device according to the seventh embodiment of the present invention.

### DETAILED EMBODIMENTS

Hereinbelow, the present invention is described based on embodiments shown in the figures.

### First Embodiment

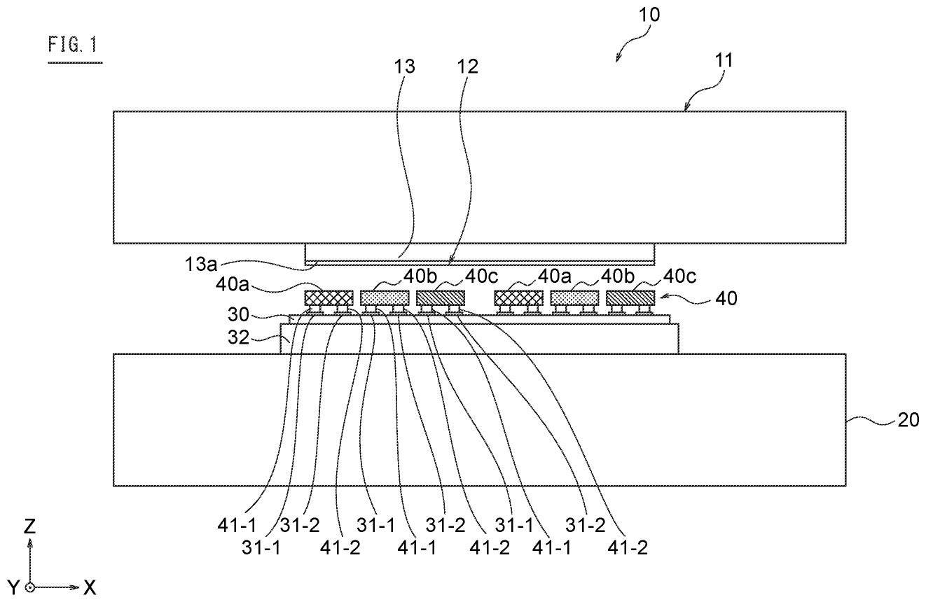

As shown in FIG. 1, a pressing device 10 according to the first embodiment includes a press plate 11. The press plate 11 is made of metals such as stainless and the like, and applies pressure to an object to be pressed (in the present embodiment, the object to be pressed is plurality of elements 40a to 40c). The pressing device 10 constitutes part of an element array manufacturing apparatus which forms the element array 40 including the plurality of elements 40a to 40c on a mounting substrate 30. In below, X-axis corresponds to a width direction of the mounting substrate 30, Y-axis corresponds to a depth direction of the mounting substrate 30, and Z-axis corresponds to a height direction of the mounting substrate 30. X-axis and Y-axis are parallel to a horizontal plane, Z-axis is parallel to a vertical line, and X-axis, and Z-axis are perpendicular to each other. Note that, in the figures such as for the convenience of explanation, the elements 40a to 40c are shown relatively large compare to the other constituting members.

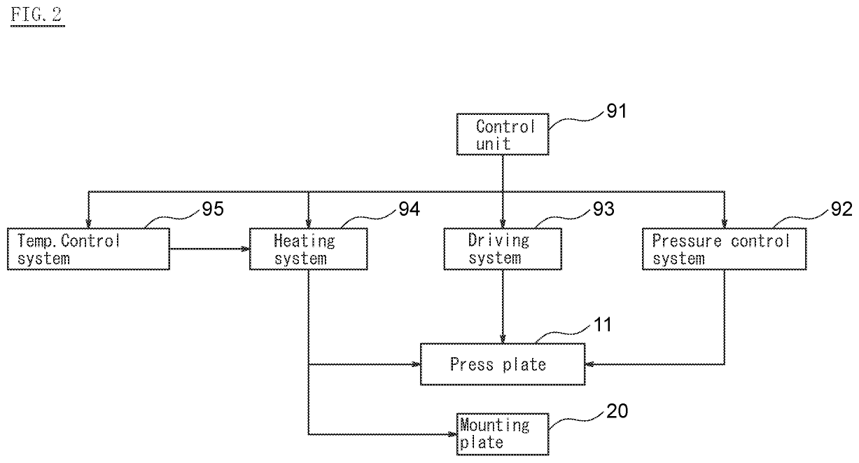

As shown in FIG. 2, the manufacturing apparatus for the element array 40 includes a control unit 91, a pressure control system 92, a driving system 93, a heating system 94, and a temperature control system 95; and the press plate 11 and so on are controlled by the above-mentioned parts. The driving system 93 moves the press plate 11 in a vertical direction. The pressure control system 92 controls the strength of pressing force (amount of load) when the press plate 11 is driven. The heating system 94 may, for example, be a heater, and it is installed to a mounting table 20 to which the press plate 11 and the mounting substrate 30 and so on are placed, as shown in FIG. 1. The temperature control system 95 controls the heating temperature, thereby controls the heating temperature of the press plate 11 and the mounting table 20. The control unit 91 controls movements of the pressure control system 92, the driving system 93, the heating system 94, and the temperature control system 95.

In FIG. 1, the mounting substrate 30 also extends in the Y-axis direction, and an outer shape of the mounting substrate 30 is a circular shape or a square shape. The material of the mounting substrate 30 of the present embodiment is a glass-epoxy material. Note that, the material of the mounting substrate 30 is not limited to this. For example, as a glass substrate may also be SiO₂, Al₂O₃; and as a flexible substrate, it may be elastomers such as polyimide, polyamide, polypropylene, polyether ether ketone, urethane, silicone, polyethylene terephthalate, polyethylene naphthalate, and the like, further it may also be a glass wool and the like.

The mounting substrate 30 is placed on the mounting table 20 via a mounting support substrate 32. At the surface of the mounting substrate 30, a conductive bonding material, which is not shown in the figure, is formed in advance. This conductive bonding material electrically and mechanically connects the mounting substrate 30 and the elements 40a to 40c by using an anisotropic conductive particle connection or a bump compression connection; and the conductive bonding material is cured by heating. As the conductive bonding material, for example, ACF, ACP, NCIF, NCP, or so may be mentioned. A thickness of the conductive bonding material may preferably be within a range of 1.0 to 10000 μm.

A conductive pattern 31_1 and a conductive pattern 31_2 are formed in a predetermined pattern to the mounting substrate 30. In the example shown in the figure, the conductive pattern 31_1 and the conductive pattern 31_2 are formed in a pair, and a plurality of pairs of the conductive patterns 31_1 and 31_2 is placed along the X-axis direction. The conductive patterns 31_1 and 31_2 can be connected to any one of the elements 40a to 40c via the conductive bonding material.

The mounting support substrate 32 is made of a thin plate (rigid body) in a form of flat plate. The mounting support substrate 32 is placed on the mounting table 20, and it is constituted by a member having a relatively high surface flatness (such as, evenness, smoothness, and so on). The mounting support substrate 32 has a better surface flatness than the mounting table 20. The surface of the mounting support substrate 32 (particularly the face at the side where the mounting table is positioned) is less rough (that is, it is smoother) and less tilted against the horizontal plane (that is, it is flatter) compared to the surface of the mounting table

The mounting support substrate 32 is constituted by a hard member, and in the present embodiment, it is constituted by a glass substrate. Note that, the material constituting the mounting support substrate 32 is not particularly limited, and it may be constituted by quartz glass SiO₂), diamond, ceramics such as sapphire, alumina (Al₂O₃), cordierite (2MgO·2Al₂O₃·5SiO₂), aluminum nitride (AlN), silicon nitride (SiN), silicon carbide (SiC), zirconia (ZrO₂), and the like. As the surface flatness, a surface roughness Ra of the mounting support substrate 32 may preferably be within a range of 0.1 to 2.0 μm, more preferably within a range of 0.1 to 1.0 μm.

In the example shown in the figure, a thickness of the mounting support substrate 32 is thicker than the mounting substrate 30 or the elements 40a to 40c. The thickness of the mounting support substrate 32 may preferably be within a range of 1 mm to 20 mm. At the surface of the mounting support substrate 32, a water repellant treatment is carried out, thereby the water repelling layer (not shown in the figure) may be formed. The water repellant treatment is carried out for example by applying a fluorine-based resin to the surface of the mounting support substrate 32. A thickness of the water repellant layer may preferably be 8 μm or less.

As such, by placing the mounting substrate 30 on the mounting support substrate 32 having an excellent surface flatness, the mounting substrate 30 can be placed stably without being tilted against the horizontal plane. Also, by forming the water repelling layer to the surface of the mounting support substrate 32, when the element array 40 is pressed using the press plate 11, the pressing part 12 contacts the conductive bonding material formed on the mounting substrate 30. Thus, even if the conductive bonding material flows to the side of the mounting support substrate 32, the water repelling layer can prevent the conductive bonding material from adhering to the mounting support substrate 32. As a result, the adhesion between the pressing part 12 and the conductive bonding material can be prevented, and the damage of the press plate 11 can be prevented.

The elements 40a to 40c are placed in an array form on the substrate 30. Here, “in an array form” means that the elements 40a to 40c are placed in a plurality of rows and columns following a predetermined pattern; and the spaces formed along the direction of rows and the direction of columns may be the same or different sizes.

The elements 40a to 40c are each aligned as individual pixel of RGB on a display board for a screen, or may be aligned on a lighting board as illuminant of backlight. The element 40a is a red light emitting element, the element 40b is a green light emitting element, and the element 40c is a blue light emitting element.

The elements 40a to 40c according to the present embodiment are micro light emitting elements (micro-LED elements); and a size (width×depth) is within a range of 5 μm×5 μm to 50 μm×50 μm. Also, a thickness (height) of each of the elements 40a to 40c is 50 μm or less.

A pair of electrodes (bumps) 41_ 1 and 41_——2 is formed to a face at one side (a face at the side where the mounting substrate 30 is placed) of each of the elements 40a to 40c. The pair of electrodes 41_1 and 41_2 respectively connects to conductive patterns 31_1 and 31_2 provided to the mounting substrate 30. The electrodes 41_1 and 41_2, for example, each has a thickness of 3 μm or less.

The elements 40a to 40c are pressed using the press plate 11, thereby the conductive bonding material is compressed which is placed between the electrodes 41_1 and 41_2 of each of the electrodes 40a to 40c and the conductive patterns 31_1 and 31_2 provided on the mounting substrate 30. Such compressed part obtains a conductivity. Thereby, the conductive patterns 31_1 and 31_2 and the electrodes 41_1 and 41_2 are electrically conducted, and the element array 40 having the plurality of elements 40a to 40c is mounted on the mounting substrate 30.

The press plate 11 includes a pressing part 12 pressing the element array 40 including the plurality of elements 40a to 40c placed on the mounting substrate 30. The pressing part 12 includes a hard member 13 in a plate shape having a surface with a higher surface flatness (such as evenness, smoothness, and so on) than a surface of the press plate 11. The hard member 13 is constituted by a thin plate (rigid body) in a form of flat plate shape.

In the present embodiment, the hard member 13 is provided on the surface of the press plate 11 (on the surface at the side where the elements 40a to 40c are placed). The hard member 13 is fixed to the surface of the press plate 11 by an adhesive means such as using adhesives and the like, or by a fixing means.

When pressure is applied using the press plate 11, the surface of the hard member 13 (the face at the side where elements 40a to 40c are placed) constitutes a contacting face or a pressing face against the element array 40. That is, in the present embodiment, the element array 40 is pressed via the hard member 13.

A surface area of the face on one side of the hard member 13 positioned at the side where the elements 40a to 40c are placed, may preferably be about the same or larger than a surface area of the element array 40 or a surface area of the mounting substrate 30. In this case, when pressure is applied with the press plate 11, the entire surface of the element array 40 can be pressed via the hard member 13. Note that, the surface area of the hard member 13 may be smaller than a surface area of the element array 40 or mounting substrate 30.

The surface flatness of the hard member 13 is relatively high and it is higher than a surface flatness of the press plate 11. The surface of the hard member 13 (particularly, the contact face against the element array 40) is less rough (in other words, it is smoother) and less tilted against the horizontal plane (that is, it is flatter) than the surface of the press plate 11.

In the present embodiment, the hard member 13 is constituted by a glass substrate. Note that, a material constituting the hard member 13 is not particularly limited, and for example, quartz glass (SiO₂), diamonds, ceramics such as sapphire, alumina (Al₂O₃), cordierite (2MgO·2Al₂O₃·5SiO₂), aluminum nitride (AlN), silicon nitride (SiN), silicon carbide (SiC), zirconia (ZrO₂), and the like may be used. Regarding the surface flatness, a surface roughness Ra of the hard member 13 may preferably be within a range of 0.1 to 2.0 μm, and more preferably within a range of 0.1 to 1.0 μm.

By setting the surface roughness Ra of the hard member 13 within such range, when pressure is applied using the press plate 11, the elements 40a to 40c are prevented from adhering to the surface of the hard member 13; and also, the contact between the surface of the hard member 13 and the surface of the element array 40 can be enhanced (becomes parallel to each other).

Also, the press plate 11 is usually constituted by metal, thus it may deform during heart treatment; however, since a heat expansion coefficient of the hard member 13 is relatively small since it is constituted using the above-mentioned materials, the hard member 13 barely deforms. Thus, when pressure is applied using the press plat 11, the contact between the surface of the element array 40 and the pressing face of the pressing part 12 (the hard member 13) is enhanced, thereby the plurality of elements 40a to 40c placed on the mounting substrate 30 can be pressed evenly.

Note that, preferably, the hard member 13 may be formed using a material with a relatively high thermal conductivity. By forming the hard member 13 using such material, when the press plate 11 is heated while pressure is applied using the press plate 11, the heat of the press plate 11 can be easily conducted to the hard member 13. Thus, a sufficient amount of heat can be conducted to the conductive bonding material through the hard member 13, thereby the electrodes 41_1 and 41_2 and the conductive patterns 31_1 and 31_2 can be connected efficiently and stably via the conductive bonding material.

In the examples shown in the figures, the hard member 13 is thinner than the mounting support substrate 32, however, the hard member 13 may be thicker than the mounting support substrate 32. The thickness of the hard member 13 may preferably be within a range of 1 mm to 20 mm.

By setting the thickness of the hard member 13 within such range, when the press plate 11 is heated while pressure is applied using the press plate 11, heat of the press plate 11 can be easily conducted to the hard member 13. Thereby, the electrodes 41_1 and 41_2 of the elements 40a to 40c and the conductive patterns 31_1 and 31_2 can be connected efficiently and stably via the conductive bonding material.

At the surface of the hard member 13, a water repelling layer (a first water repelling layer) 13a is formed. The water repelling layer 13a is formed by carrying out a water repellant treatment to the surface of the hard member 13 (in the examples shown in the figures, it is the surface at one side of the hard member 13 where the elements 40a to 40c are positioned). The water repellant treatment is carried out by applying, for example, a fluorine-based resin to the surface of the hard member 13. A thickness of the water repelling layer 13a may preferably be thinner than the thickness of the hard member 13, and preferably it may be 8 μm or less.

Next, a method of producing the element array 40 on the mounting substrate 30 is described.

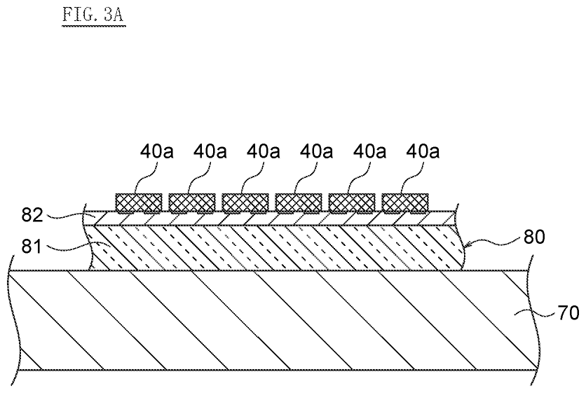

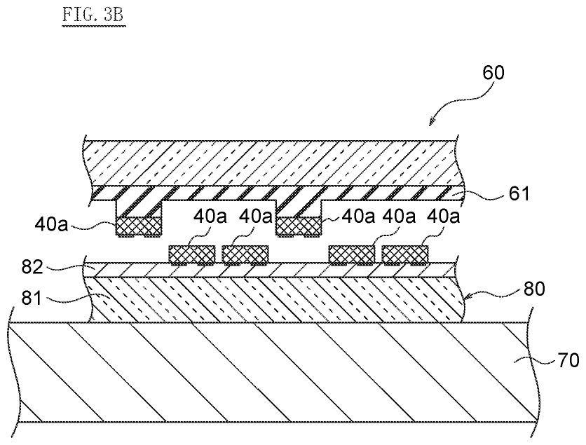

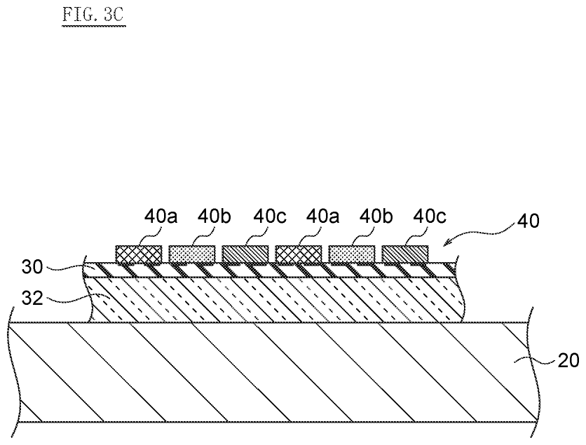

First, as shown in FIG. 1, the mounting substrate 30 on which the plurality of elements 40a to 40c are placed is prepared. The mounting substrate 30 is produced by following steps, for example, as shown in FIGS. 3A. to 3C. That is, as shown in FIG. 3A, the supply substrate 80 on which a plurality of elements 40a are placed is prepared, and the supply substrate 80 is placed on the supply table 70. The supply substrate 80, for example, includes a substrate main body 81, and an adhesive layer 82 formed on the surface of the substrate main body 81. The adhesive layer 82, for example, may be constituted of resins such as a natural rubber, a synthetic rubber, an acrylic resin, silicone rubber, and the like. Note that, the substrate main body 81 itself may be an adhesive sheet having a flexibility. At the surface of the adhesive layer 82, the elements 40a are adhered in a detachable manner and arranged in a matrix form along X-axis direction and Y-axis direction taking predetermined spaces between each element 40a.

As shown in FIG. 3B, a stamp tool 61 of a transferring machine 60 is moved to the supply table 70, and the plurality of elements 40a adhered to the adhesive layer 82 is picked up from the supply substrate 80. Then, as shown in FIG. 3C, the stamp tool 61 is moved to the mounting table 20, and the plurality of elements 40a being picked up is transferred to (placed on) the mounting substrate 30. Note that, the stamp tool 61 includes the plurality of raised portions arranged by taking predetermined space in between each of the raised portions; and by adhering the plurality of elements 40a to the adhesive layer (not shown in the figures) formed on the surface of the raised portions, the plurality of elements 40a can be picked up. The plurality of elements 40a placed on the mounting substrate 30 adheres to the conductive bonding material (not shown in the figures) formed on the mounting substrate 30.

Similarly, the supply substrate 80 (not shown in the figures) is prepared on which the plurality of elements 40b is placed, then it is placed on the supply table 70. Then, the stamp tool 61 is moved to the supply table 70, the plurality of elements 40b is picked up from the supply substrate 80, and the stamp tool 61 moves to the mounting table 20, then the plurality of elements 40b being picked up is transferred (placed on) the mounting substrate 30. Also, the supply substrate 80 (not shown in the figures) is prepared on which the plurality of elements 40c is placed, then it is placed on the supply table 70. Then, the stamp tool 61 moves to the supply table 70, the plurality of elements 40c is picked up from the supply substrate 80, and the stamp tool 61 moves to the mounting table 20, then the plurality of elements 40c being picked up is transferred to (placed on) the mounting substrate 30. Thereby, the mounting substrate 30 can be prepared on which the plurality of elements 40a to 40c as shown in FIG. 3C.

Next, the element array 40 having the plurality of elements 40a to 40c which has been transferred on the mounting substrate 30 with the stamp tool 61 is pressed using the hard member 13 provided on the surface of the press plate 11. A heating temperature of the press plate 11 while pressing is about 500° C. or so. Thereby, the plurality of elements 40a to 40c is pressed towards the conductive bonding material provided on the mounting substrate 30; thus, the plurality of elements 40a to 40c (electrodes 41_1 and 41_2 is electrically connected to the mounting substrate 30 (the conductive patterns 31_1 and 31_2) via the conductive bonding material. As discussed in above, the element array 40 can be formed on the mounting substrate 30.

In the pressing device 10 of the element array 40 according to the present embodiment, the pressing part 12 includes the hard member 13 of a plate shape having a surface with a higher surface flatness than the surface of the press plate 11. Therefore, when pressure is applied using the press plate 11, the element array 40 having the plurality of elements 40a to 40c placed on the mounting substrate 30 can be pressed via the hard member 13. The surface flatness (such as evenness, smoothness, and so on) of the hard member 13 is higher compared to the surface flatness (such as evenness, smoothness, and so on) of the press plate 11, thus the contact between the surface of the element array 40 and the like and the pressing face (the contacting face against the element array 40) of the pressing part 12 (the hard member 13) is enhanced (becomes parallel to each other), thus the plurality of elements 40a to 40c placed on the mounting substrate 30 can be pressed evenly. Therefore, the pressing device 10 for the element array 40 according to the present embodiment can prevent the mounting malfunction, and allows to stably form the element array 40 on the mounting substrate 30.

Also, in the present embodiment, the hard member 13 is provided on the surface of the press plate 11. Thus, even if the surface flatness of the press plate 11 is not necessarily good, this can be directly absorbed by the hard member 13. Therefore, the mounting malfunction can be effectively prevented, and the element array 40 can be stably formed on the mounting substrate 30.

Also, in the present embodiment, the water repelling layer 13a is formed on the surface of the hard member 13 by carrying out a water repellant treatment. Thus, when the element array 40 formed on the mounting substrate 30 is pressed via the surface of the hard member 13, adhesion of the elements 40a to 40c to the surface of the hard member 13 can be prevented, and the mounting malfunction can be effectively prevented. Also, when the plurality of elements 40a to 40c is mounted on the mounting substrate 30 using the conductive bonding material, even if the pressing part 12 contacts the conductive bonding material when pressure is applied using the pressing part 12, the water repelling layer 13a enables to prevent the adhesion of the pressing part 12 to the conductive bonding material.

Also, in the present embodiment, the water repelling layer 13a is thinner than the hard member 13. Hence, the adhesion and the like of the elements 40a to 40c to the surface of the hard member 13 can be effectively prevented.

Also, in the present embodiment, the transferring machine 60 (the stamp tool 61) moves to the supply table 70 and picks up the plurality of elements 40a to 40c from the supply substrate 80, and moves to the mounting table 20 and transfers the plurality of elements 40a to 40c being picked up to the mounting substrate 30. Therefore, during a so-called mass-transfer, the plurality of elements 40a to 40c is transferred to the mounting substrate 30 from the supply substrate 80 all at once, and the element array 40 including these elements 40a to 40c is pressed using the press plate 11, thus the element array 40 can be stably produced on the mounting substrate 30, and the yield during the production can be improved.

Also, in the present embodiment, the plurality of elements 40a to 40c is pressed towards the conductive bonding material provided on the mounting substrate, thereby the plurality of elements 40a to 40c is connected to the mounting substrate 30. Hence, the plurality of elements 40a to 40c can be mounted on the mounting substrate 30 using the conductive bonding material such as ACF (Anisotropic Conductive File), ACP (Anisotropic Conductive Paste), and the like, thus the element array 40 can be easily formed on the mounting substrate 30.

Also, in the present embodiment, the thickness of each of the elements 40a to 40c is 50 μm or less. Even in case that the element array 40 including very small elements 40a to 40c such as mentioned in above is the object to be pressed, the resilient member 14 moderately deforms in a way which follows the surface shape of the element array 40 and the like, thus the plurality of elements 40a to 40c constituting the element array 40 can be evenly pressed.

### Second Embodiment

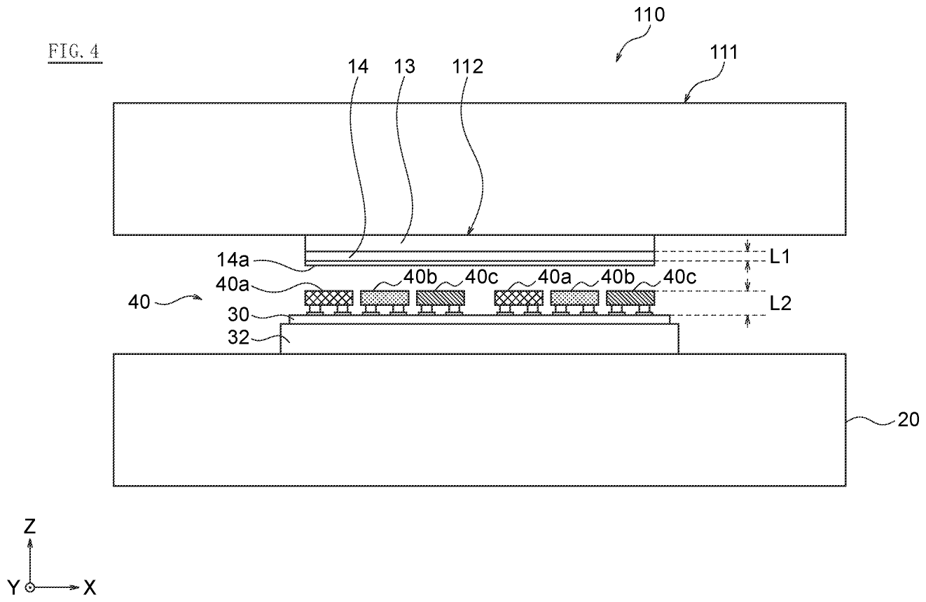

A pressing device 110 according to the embodiment shown in FIG. 4 has the same configurations and exhibits the same effects as the pressing device 10 according to the first embodiment, except for as described in below. In FIG. 4, a member in common with the constituting member of the pressing device 10 of the first embodiment is given the same reference number, and the explanation of the same constituting members is omitted.

As shown in FIG. 4, the pressing device 110 includes a press plate 111. The press plate 111 includes a pressing part 112, and the pressing part 112 further includes a resilient member 14 in addition to the hard member 13 provided on the surface of the press plate 111, which is different from the pressing part 12 of the first embodiment.

The resilient member 14 is in a form of a flat plate shape (a sheet like shape), and it is provided to the surface of the hard member 13. The resilient member 14 is fixed to the surface of the hard member 13 by an adhesive means such as using adhesives and so on, or by a fixing means. When pressure is applied using the press plate 111, the surface of the resilient member 14 (the face at the side where the elements 40a to 40c are placed) constitutes the contacting face or the pressing face against the element array 40. That is, in the present embodiment, the element array 40 is pressed via the resilient member 14.

A surface area of the face at one side of the resilient member 14 positioned at the side where the elements 40a to 40c are placed may be equal to or larger than the surface area of the element array 40 or the mounting substrate 30. In this case, when pressure is applied using press plate 111, the entire surface of the element array 40 can be pressed via the resilient member 14. Note that, the surface area of the resilient member 14 may be smaller than the surface area of the element array 40 or the mounting substrate 30.

In the present embodiment, the resilient member 14 may be constituted. by a carbon sheet. Note that, the material constituting the resilient member 14 is not particularly limited, and for example, it may be a sheet constituted by heat-resistant resins such as polyimide, polytetrafluoroethylene (Teflon®), polypropylene, and the like; elastomers such as urethane, silicone, polyethylene terephthalate, polyethylene naphtholate, and the like; and glass wool and the like.

Note that, the resilient member 14 may preferably be constituted by a material with a relatively high thermal conductivity. By forming the resilient member 14 using such material, when the press plate 111 is heated while pressure is applied using the press plate 111, the heat of the press plate 111 can be easily conducted to the resilient member 14. Thus, a sufficient amount of heat can be conducted to the conductive bonding material through the resilient member 14, thereby the electrodes 41_1 and 41_2 and the conductive patterns 31_1 and 31_2 can be connected efficiently and stably via the conductive bonding material.

A thickness L1 of the resilient member 14 may preferably be 1 mm or less. A proportion L1/L2 of the thickness L1 of the resilient member 14 to the thickness L2 (height) of each of the elements 40a to 40c may preferably be within a range of 0.5 to 2.0. Note that, the thickness L2 of each of the elements 40a to 40c corresponds to a total sum of a thickness of an element body and a thickness of the electrode 41_1 or 41_2. When the proportion of the thickness of the resilient member to the thickness of each of the elements 40a to 40c is set within such range, the resilient member 14 has an adequate thickness. Thus, the resilient member 14 easily deform moderately following the surface shape of the element array 40, hence pressure can be thoroughly applied to the entire element array 40. Also, since the resilient member 14 has an adequate rigidity, sufficient pressing force can be applied to the element array 40 via the resilient member 14. Therefore, the plurality of elements 40a to 40c placed on the mounting substrate 30 can be evenly pressed.

Further, pressure is also generated when the resilient member 14 deforms, however, when the thickness of the resilient member 14 to the thickness of each of the elements 40a to 40c is set within such proportion, said pressure is not significantly large to impact the pressing force of the press plate 111. Therefore, when pressure is applied using the press plate 111, uneven distribution of the pressing force of the press plate 111 can be prevented, and the elements 40a to 40c placed on the mounting substrate 30 can be pressed evenly.

Also, in case the thickness of resilient member 14 is set within such range, when the press plate 111 is heated while pressure is applied using the press plate 111, the heat of the press plate 111 can be easily conducted to the resilient member 14. Thus, a sufficient amount of heat can be conducted to the conductive bonding material via the resilient member 14, thereby the electrodes 41_1 and 41_2 and the conductive patterns 31_1 and 31_2 can be connected efficiently and stably via the conductive bonding material.

A water repelling layer (second water repelling layer) 14a is formed on the surface of the resilient member 14. The water repelling layer 14a is formed by carrying out a water repellant treatment to the surface of the resilient member 14 (in the examples shown in the figures, it is the surface at one side of the resilient member 14 where the elements 40a to 40c are positioned). The water repellant treatment is carried out by applying, for example, a fluorine-based resin to the surface of the resilient member 14. A thickness of the water repelling layer 14a may preferably be thinner than the thickness of the resilient member 14, and preferably it may be 8 μm or less.

In the present embodiment, the pressing part 112 includes the resilient member 14 in a plate shape, and the resilient member 14 is provided on the surface of the hard member 13. In this case, when pressure is applied using the press plate 111, the plurality of elements 40a to 40c placed on the mounting substrate 30 can be pressed via the resilient layer 14. The resilient member 14 moderately deforms following the surface shape of the element array 40, thus the plurality of elements 40a to 40c placed on the mounting substrate 30 can be pressed more evenly.

Also, in the present embodiment, a water repelling layer 14a, obtained by carrying out the water repellant treatment, is formed on the surface of the resilient member 14. Thus, when the element array 40 formed on the mounting substrate 30 is pressed via the surface of the resilient layer 14, adhesion of the elements 40a to 40c to the surface of the resilient member 14 can be prevented, and the mounting malfunction can be effectively prevented. Also, when the plurality of elements 40a to 40c is mounted on the mounting substrate using the conductive bonding material, even if the pressing part 112 contacts the conductive bonding material while pressure is applied using the press plate 111, the water repelling layer 14a can prevent the conductive bonding material from adhering to the pressing part 112. Thus, damages to the press plate 111 can be prevented which is caused when the conductive bonding material adheres to the pressing part 112.

Also, in the present embodiment, the water repelling layer 14a is thinner than the resilient member 14. Thus, the adhesion and the like of the elements 40a to 40c to the surface of the resilient member 14 can be effectively prevented.

Also, in the present embodiment, the hard member 13 is provided on the surface of the press plate 111, and the resilient member 14 is provided on the surface of the hard member 13. Hence, even if the surface flatness of the press plate 111 is not necessarily good, this can be directly absorbed by the hard member 13. Therefore, the resilient member 14, which constitutes the contacting face against the element array 40, can be placed approximately parallel to the horizontal plane; thus, the contact between the surface of the element array 40 and the like and the pressing face (the contacting face against the element array 40) of the pressing part 112 (the resilient member 14) can be enhanced (becomes parallel to each other). Further, the plurality of elements 40a to 40c placed on the mounting substrate 30 can be pressed evenly, which allows to prevent the mounting malfunction, and the element array 40 can be stably formed on the mounting substrate 30.

Also, when the surface roughness Ra of the hard member 13 is set within the range shown in the first embodiment (preferably within a range of 0.1 to 2.0 μm, more preferably within a range of 0.1 to 1.0 μm), the resilient member 14 can be provided on the surface of the hard member 13 while the tilting against the horizontal plane is reduced, and when pressure is applied using the press plate 111, the contact between the surface of the hard member 13 and the surface of the element array 40 can be enhanced (becomes parallel to each other). Note that, the water repelling layer 14a may be provided on the surface of the hard member 13. In this case, the surface roughness Ra mentioned in above preferably may be a value including the thickness of the water repelling layer 14a.

### Third Embodiment

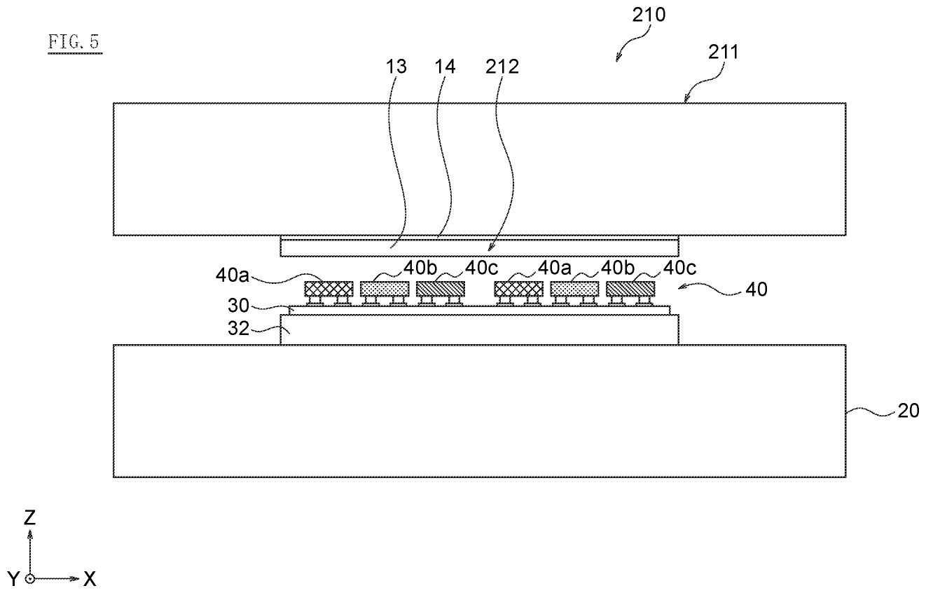

A pressing device 210 shown in FIG. 5 has the same configurations and exhibits the same effects as the pressing device 110 according to the second embodiment, except for as described in below. In FIG. 5, a member in common with the constituting member of the pressing device 110 of the second embodiment is given with the same reference number, and the explanation of such member is omitted.

As shown in FIG. 5, the pressing device 210 includes a press plate 211, and the press plate 211 includes a pressing part 212. As it is obvious by comparing FIG. 4 and FIG. 5, the order of the hard member 13 and the resilient member 14 is other way around in the pressing part 212. That is, in the present embodiment, the resilient member 14 is provided on the surface of the press plate 211, and the hard member 13 is provided on the surface of the resilient member 14. Note that, in the example shown in the figure, the water repelling layer 13a shown in FIG. 1 is not provided on the surface of the hard member 13, however, in reality it is provided.

In this case, the resilient member 14 functions as a cushion material, and as the resilient member 14 deforms freely, the hard member 13 can tilt or change the position following the deformed shape of the resilient member 14. By moderately deforming the resilient member 14, the surface of the element array 40 and the surface of the hard member 13 which constitutes the contacting face against the element array 40 tend to easily become parallel to each other, thus the plurality of elements 40a to 40c constituting the element array 40 can be pressed more evenly.

### Fourth Embodiment

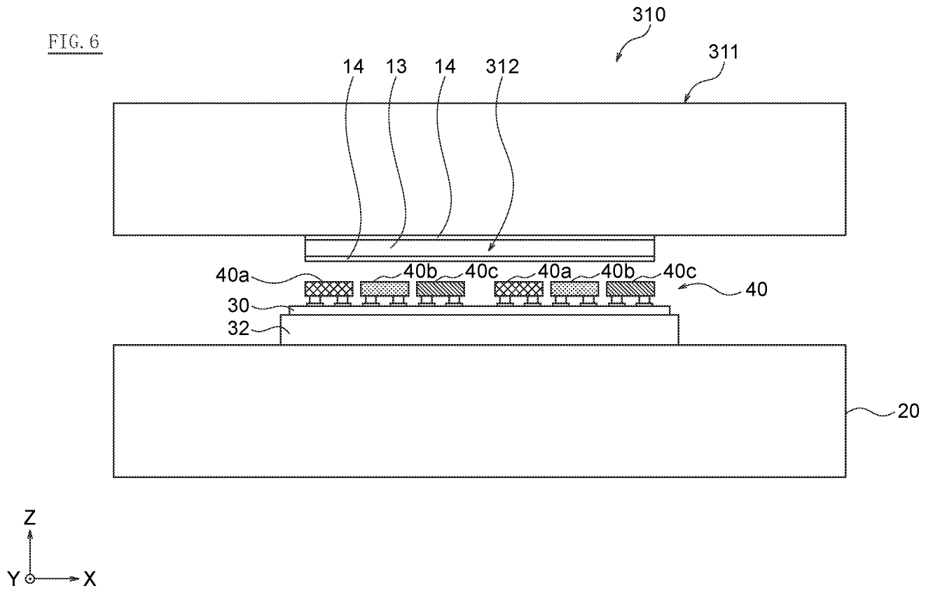

A pressing device 310 shown in FIG. 6 has the same configuration and exhibits the same effects as the pressing device 210 according to the third embodiment, except for as described in below. In FIG. 6, a member in common with the constituting member of the pressing device 210 of the third embodiment is given with the same reference number, and the explanation of such member is omitted.

As shown in FIG. 6, the pressing device 310 includes a press plate 311. The press plate 311 includes a pressing part 312. A resilient member 14 is provided on the surface of the pressing part 312, which is different from the pressing part 212 of the third embodiment. In the present embodiment, the resilient member 14 is provided on the surface of the press plate 311, the hard member 13 is provided on the resilient member 14, and another resilient member 14 is provided on the hard member 13.

That is, in the present embodiment, at least one hard member 13 (one hard member in the example shown in the figure) and at least one resilient member 14 (two resilient members in the example shown in the figure) are stacked in an alternating manner on the surface of the press plate 311. Thus, the pressing part 312 is constituted of the hard member 13 and the resilient members 14 which is total of three layers. Note that, in the example shown in the figure, the water repelling layer 14a shown in FIG. 4 is not formed on the resilient member 14 which is provided on the surface of the hard member 13, however in reality, the water repelling layer 14a is formed.

In the present embodiment, at least one hard member 13 and at least one resilient member 14 are stacked in an alternating manner on the surface of the press plate. In this case, the effect obtained by providing the hard member 13 to the press plate 11 (the effect mentioned in the first embodiment) and the effect obtained by providing the resilient member 14 to the press plates 111 and 211 (that is the effects mentioned in the second and third embodiments) both can be obtained; thus, the plurality of elements 40a to 40c placed on the mounting substrate 30 can be pressed further evenly.

In the present embodiment, the hard member 13 is provided on the surface of the resilient member 14, and another resilient member 14 is provided on the surface of the hard member 13. The surface flatness (for example, evenness, smoothness, and the like) of the hard member 13 is higher than the surface flatness (for example, evenness, smoothness, and the like) of the press plate 311, thus by providing the hard member 13 in between the resilient members 14, the resilient member 14 at the outer side constituting the contacting face against the element array 40 can be placed approximately parallel to the horizontal plane. Therefore, the contact between the surface of the element array 40 and the pressing face (the contacting face against the element array 40) of the pressing part 312 (the resilient member 14 of the outer side) is enhanced (becomes parallel to each other), thus the plurality of elements 40a to 40c placed on the mounting substrate 30 can be pressed evenly. Therefore, the mounting malfunction can be effectively prevented and the element array 40 can be stably formed on the mounting substrate 30.

Also, as the resilient member 14 provided on the surface of the press plate 311 deforms, the surface of the element array 40 and the like and the surface of the resilient member 14 at the outer side which constitutes the contacting surface against the element array 40 easily become parallel to each other, hence the plurality of elements 40a to 40c constituting the element array 40 can be pressed further evenly.

### Fifth Embodiment

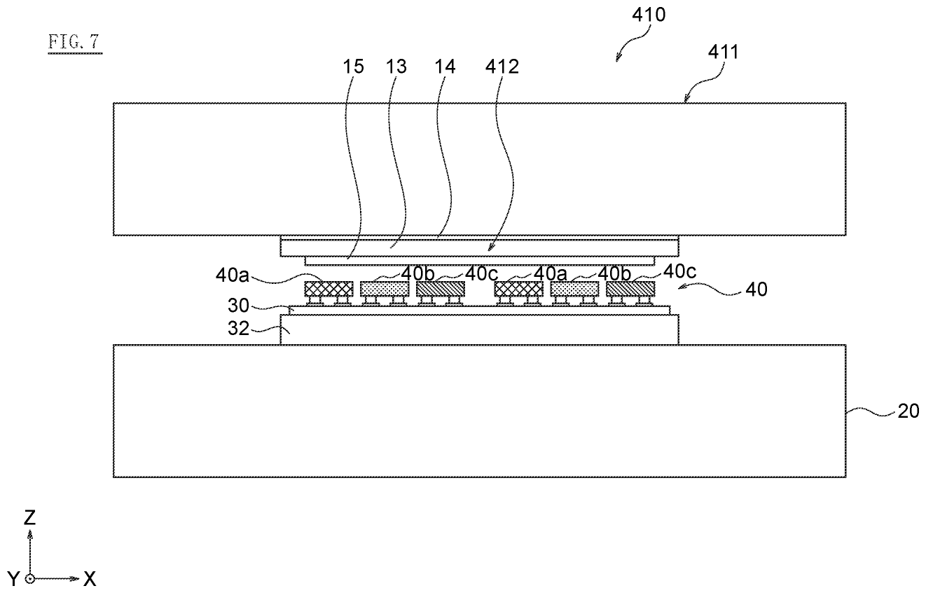

A pressing device 410 shown in FIG. 7 has the same configurations and the same effects as the pressing device 310 according to the fourth embodiment, except for as described in below. In FIG. 7, a member which is in common with the constituting member of the pressing device 310 of the fourth embodiment is given with the same reference number, and the explanation of such member is omitted.

As shown in FIG. 7, the pressing device 410 includes a press plate 411. The press plate 411 includes the pressing part 412, and the pressing part 412 includes a resilient member 15 in addition to the hard member 13 and the resilient member 14, which is different from the pressing part 312 of the fourth embodiment. The resilient member 15 is provided on the surface of the hard member 13.

The resilient member 15 has a different shape from the resilient member 14, and the resilient member 15 is smaller in X-axis width and/or Y-axis width compared to the resilient member 14. Also, the resilient member 15 is thicker than the resilient member 14. A material constituting the resilient member 15 may be the same or different from the resilient member 14. Note that, in the example shown in the figure, a water repelling layer (the water repelling layer equivalent to the water repelling layer 14a shown in FIG. 4) is not formed on the resilient member 15, however in reality it is formed.

As such, even in case the resilient member 15 having different shape and made of different materials from the resilient member 14 is provided on the surface of the hard member 13, the same effects as in case of the fourth embodiment can be obtained.

### Sixth Embodiment

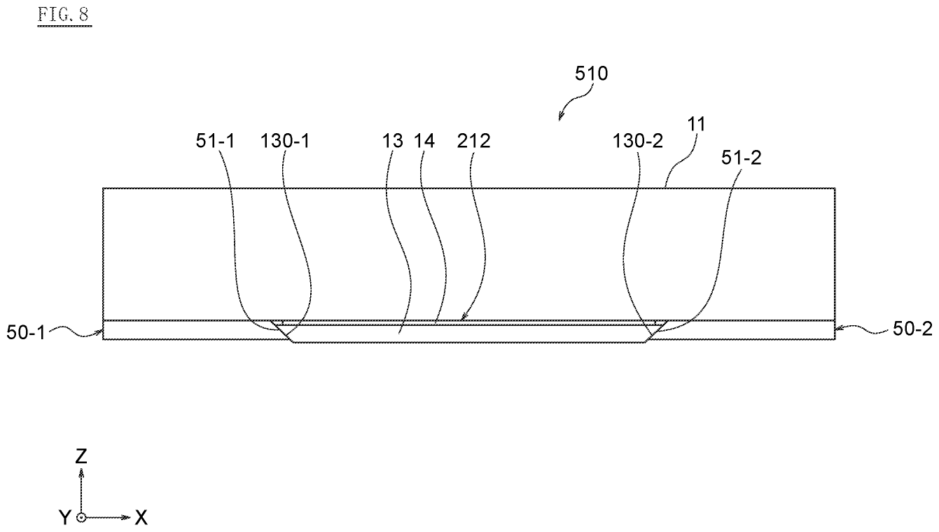

A pressing device 510 shown in FIG. 8 has the same configurations and exhibit the same effects as the pressing device 210 according to the third embodiment, except for as described in below. In FIG. 8, a member which is in common with the constituting member of the pressing device 210 of the third embodiment is given with the same reference number, and the explanation of such member is omitted.

As shown in FIG. 8, the pressing device 510 includes clamping members (brackets) 50_1 and 50_2. The clamping member 50_1 is placed at one end of the X-axis direction of the hard member 13 to fix one end of the hard member 13. The clamping member 50_2 is placed at the other end of the X-axis direction of the hard member 13 to fix the other end of the hard member 13.

Specifically, the clamping members 50_1 and 50_2 include clamping slant parts 51_1 and 51_2 formed so that these are tilting towards the YZ plane. Also, the hard member 13 includes taper parts 130_1 and 130_2 formed so that these are tilting towards the YZ plane. The taper part 130_1 is formed at one end in the X-axis direction of the hard member 13, and the taper part 130_2 is formed at the other end in the X-axis of the hard member 13. The clamping slant part 51_1 engages (contacts) with the taper part 130_1, and the clamping slant part 51_2 engages (contacts) with the taper part 130_2. Thereby, the hard member 13 is fixed so that it is held between the clamping slant parts 51_1 and 51_2, and it is fixed at the inner side in the X-axis direction of the clamping slant parts 51_1 and 51_2.

The taper part 130_1 is fixed using the clamping slant part 51_1, and the taper part 130_2 is fixed using the clamping slant part 51_2, thereby the hard member 13 can be fixed to the press plate 11 in a detachable manner due to the clamping members 50_1 and 50_2. Note that, the clamping members 50_1 and 50_2 are fixed to the press plate 11 with bolts and the like.

In the present embodiment, the hard member 13 is provided to the press plate 11 in a detachable manner. Thus, the hard member 13 provided to the press plate 11 can be easily exchanged to another hard member 13. Also, when the hard member 13 is detached, the resilient member 14 can be also detached, the resilient member 14 can also be easily exchanged to another resilient member 14. Also, depending on the types of the elements 40a to 40c and on the shapes of the mounting substrate 30 and so on, the hard member 13 and/or the resilient member 14 provided to the press plate 11 can be exchanged to an appropriate hard member 13 and/or resilient member 14.

Also, in the present embodiment, the hard member 13 is fixed to the press plate 11 using the clamping members 50_1 and 50_2. Therefore, the hard member 13 can be fixed to the press plate 11 with a sufficient fixing strength using the clamping members 50_1 and 50_2. Also, the hard member 13 can be easily detached from the press plate 11, therefore the hard member 13 and the resilient member 14 can be easily exchanged.

### Seventh Embodiment

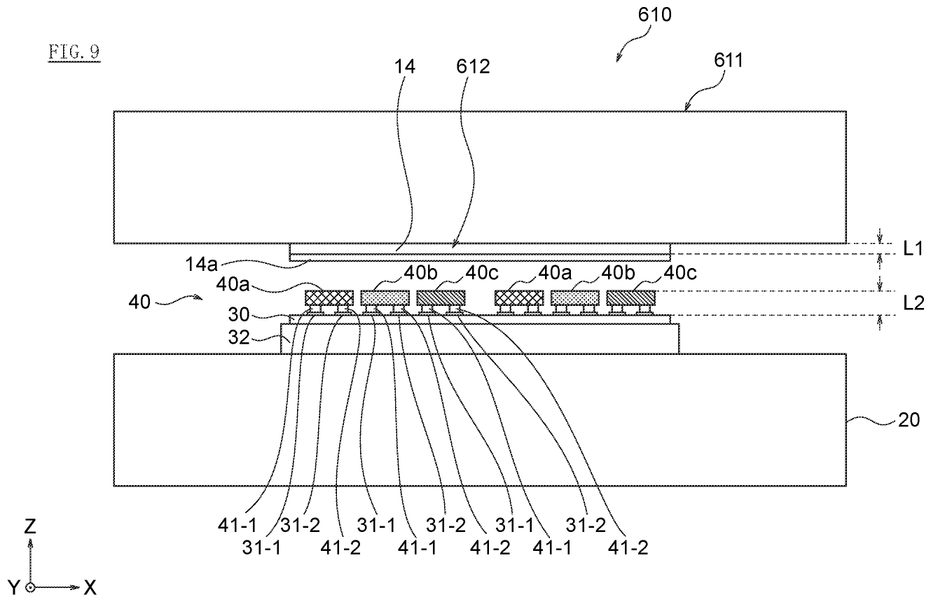

The pressing device 610 according to the embodiment shown in FIG. 9 has the same configuration and exhibit the same effects as the pressing device 110 according to the second embodiment, except for as described in below. In FIG. 9, the same reference number is given to the member which is common with the constituting member of the pressing device 110 of the second embodiment, and the explanation of such member is omitted.

As shown in FIG. 9, the pressing device 610 includes a press plate 611, The press plate 611 incudes a pressing part 612, and in the pressing part 612, the resilient member 14 is directly provided on (contacting) the surface of the press plate 11, which is different from the pressing part 112 of the second embodiment. The resilient member 14 is fixed to the surface of the press plate 611 with an adhesive means such as using adhesives and the like, or with a fixing means. When pressure is applied using the press plate 611, the surface of the resilient member 14 (the face at the side where the elements 40a to 40c are positioned) constitutes a contacting face or a pressing face against the element array 40. That is, in the pressing device 610 of the element array 40 according to the present embodiment, when pressure is applied using the press plate 611, the element array 40 including the plurality of elements 40a to 40c placed on the substrate 30 can be pressed via the resilient member 14. Note that, at the surface of the resilient member 14, the water repelling layer 14a is formed.

In the present embodiment, the resilient member 14 has a suitable thickness (that is, a proportion L1/L2 of a thickness L1 of the resilient member 14 to a thickness L2 of each of the elements 40a to 40c preferably within a range of 0.5 to 2.0), thus the resilient member 14 easily deforms moderately following the surface shape of the element array 40 and the like, thus pressure can be thoroughly applied to the entire element array via the resilient member 14. Also, since the resilient member 14 has a suitable hardness, a sufficient pressing force can be applied to the element array 40 via the resilient member 14. Therefore, the plurality of elements 40a to 40c placed on the mounting substrate 30 can be evenly pressed.

In the present embodiment, the resilient member 14 is provided on the surface of the press plate 611. Thus, when the press plate 611 is heated while pressure is applied using the press plate 611, the heat of the press plate 611 can be easily conducted to the resilient member 14, hence the elements 40a to 40c can be stably mounted on the mounting substrate 30 using the conductive bonding material provided on the mounting substrate 30.

### EXAMPLES

Hereinbelow, the present invention is further described by referring to the detailed examples, however, the present invention is not limited thereto,

### Example 1

As shown in FIG. 9, a sample of a mounting substrate 30 on which elements 40a to 40c were placed was prepared, and a resilient member 14 was provided on a surface of a press plate 611 of a pressing device 610. As the resilient member 14, a carbon sheet was used. A thickness L1 of the resilient member 14 was 5 μm, a thickness L2 of each element of the elements 40a to 40c was 8 μm (a thickness of an element body: 5 μm and a thickness of an electrode: 3 μm), a proportion L1/L2 of the thickness L1 of the resilient member 14 to the thickness L2 of each of the elements 40a to 40c was 1.60.

A water repelling layer 14a formed by a water repelling coating was formed in a thickness of 0.05 μm on a surface of the resilient member 14 (on the surface at one side of the resilient member 14 where the elements 40a to 40c were positioned).

Ten of the same samples were made, and each sample was pressed using the press plate 611 which the resilient member 14 was provided on its surface. Then, the surface of the mounting substrate 30 was observed, and a mounting malfunction was evaluated. Among the ten samples, when no mounting malfunction was observed, then it was evaluated “GOOD”, and when even a small mounting malfunction was observed, then it was evaluated “NG”. Results are shown in Table 1.

### Examples 2 to 3 and Comparative Examples 1 to 2

The same evaluation as Example 1 was carried out, except that the thickness L1 of the resilient member 14 provided on the surface of the press plate 611 was changed from Example 1, and a proportion L1/L2 of the thickness L1 of the resilient member 14 to the thickness (height) L2 of each of the elements 40a to 40c was changed. Results are shown in Table 1.

TABLE 1

| | Thickness | Thickness | Proportion | |
|---|---|---|---|---|
| | L1 of the | L2 | L1/L2 of | |
| | resilient | of | resilient, member | |
| | member | element | thickness to | |
| No. | (μ m) | (μ m) | element thickness | Evaluation |
| Comparative | 3 | 8 | 0.38 | NG |
| example 1 | | | | |
| Example 1 | 5 | 8 | 0.63 | GOOD |
| Example 2 | 10 | 8 | 1.25 | GOOD |
| Example 3 | 15 | 8 | 1.88 | GOOD |
| Comparative | 20 | 8 | 2.50 | NG |
| example 2 | | | | |

### Evaluation

As shown in Table 1, when the proportion L1/L2 of the thickness L1 of the resilient member 14 to the thickness (height) L2 of each of the elements 40a to 40c was within a range of 0.5 to 2.0, it was confirmed that no mounting malfunction had occurred, and the element array 40 was stably formed on the mounting substrate 30.

Note that, the present invention is not limited to the embodiments mentioned in above, and it may be variously modified within a scope of the present invention.

In the first embodiment, micro-LEDs were mentioned as an example of the elements 40a to 40c mounted on the mounting substrate 30, however, elements other than micro-LEDs may be mounted on the mounting substrate 30. For example, the elements 40a to 40c are components used for an electronic circuit, these may be chips such as MEMS, semiconductor elements, resistance, capacitors, and so on. The semiconductor elements include discrete semiconductors such as transistors, diodes, LED, thyristors, and the like; and integrated circuits such as IC, LSI, and the like. Also, LED includes a mini-LED and the like. When such element was used, the thickness (height) of each of the elements 40a to 40c may preferably be 100 μm or less, and more preferably 50 μm or less. The same applies to the second embodiment to the seventh embodiment.

In the first embodiment, the surface of the hard member 13 and/or the surface of the water repelling layer 13a may have roughness (the surface roughness Ra:0.1 to 1.0 μm) which is smaller than roughness formed on the surface of the press plate 11. In this case, when pressure is applied using the press plate 11, the elements 40a to 40c can be prevented from adhering to the surface of the pressing part 12 (the hard member 13), and the mounting malfunction can be effectively prevented. The same applies to the third embodiment.

In the second embodiment, the surface of the resilient member 14 and/or the surface of the water repelling aver 14a may have roughness (the surface roughness Ra:0.1 to 1.0 μm) which is smaller than roughness formed on the surface of the press plate 11. In this case, when pressure is applied using the press plate 11, the elements 40a to 40c can be prevented from adhering to the surface of the pressing part 12 (the resilient member 14), and the mounting malfunction can be effectively prevented. The same applies to the fourth embodiment and the seventh embodiment. Also, in regards with the above-mentioned fifth embodiment, the same roughness may be formed on the surface of the resilient member 15 or on the surface of the water repelling layer provided on the resilient member 15.

In the first embodiment, the water repelling layer 13a is provided only to the face at one side of the hard member 13 (to the face at the side where the plurality of elements 40a to 40c is positioned), however, the water repelling layer 13a may also be provided to a face at the opposite side. Also, in the second embodiment, the water repelling layer 14a is provided only to a face at one side of the resilient member 14 (to the face at the side where the plurality of elements 40a to 40c is positioned), however, the water repelling layer 14a may also be provided to a face at the opposite side. The same applies to third embodiment to the sixth embodiment.

Also, in the second embodiment, the water repelling layer 13a may be provided to the surface of the hard member 13 (to one face or to both faces). Similarly, in the third embodiment, the water repelling layer 14a may be provided to the surface of the resilient member 14 (to one face or to both faces). Also, in the fourth embodiment, when the plurality of hard members 13 and/or resilient members 14 is provided to the pressing part 312, the water repelling layer 13a and the water repelling layer 14a may be respectively provided to each of them.

In the fourth embodiment, one hard member 13 and two resilient members 14 are provided to the pressing part 312, however, the number of hard member 13 and resilient member 14 is not particularly limited to this, and it may be more than mentioned in above. For example, two hard members 13 and two resilient members 14 may be provided to the pressing part 312, or two hard members 13 and three resilient members 14 may be provided to the pressing part 312.

In the fourth embodiment, the hard member 13 may be provided to the surface of the press plate 111, the resilient member 14 may be provided to the surface of the hard member 13, and another hard member 13 may be provided to the surface of the resilient member 14. In this case, a plurality of hard members 13 and/or resilient members 14 may be provided to the pressing part 312.

In the fifth embodiment, the shape of the resilient member 15 is not particularly limited to the example shown in the figure, and it may be changed accordingly. Also, the arrangement of the resilient member 14 and the resilient member 15 may be switched. Also, by applying the technology shown in the fourth embodiment to the pressing device 410 of the fifth embodiment, at least one hard member 13, at least one resilient member 14, and at least one resilient member 15 may be stacked on the surface of the press plate 411 in an alternating manner.

In the first embodiment, the mounting support substrate 32 may be omitted. The same applies to the second embodiment to the seventh. embodiment.

In the first embodiment, the method of mounting the elements 40a to 40c to the mounting substrate using heat compression bonding is shown, however, the elements 40a to 40c may be mounted on the mounting substrate 30 using a method of solid phase bonding, anodic bonding, and other methods. The same applies to the second to seventh embodiment.

In the second embodiment, the water repelling layer 14a is provided only to the surface at one side of the resilient member 14 (to the face at the side where the plurality of elements 40a to 40c is positioned), however, the water repelling layer 14a may also be provided to the opposite side of the surface. The same applies to the fourth embodiment to the fifth embodiment and also to the seventh embodiment.

In the third embodiment, the water repelling layer may be provided also to the surface of the resilient member 14 (to the both sides or to one side). The same applies to the resilient member 14 of the fourth embodiment (the resilient member 14 contacting the press plate 311) and to the resilient member 14 of the fifth embodiment. Note that, in this case, preferably the thickness of the water repelling layer may also be 8 μm or less.

In the fourth embodiment, the hard member 13 may be provided to the surface of the press plate 311, the resilient member 14 may be provided to the surface of the hard member 13, another hard member 13 may be provided to the surface of the resilient member 14, and another resilient member 14 may be provided to the surface of said another hard member 13. Also, in this case, additional hard member 13 and resilient member 14 may be further provided to the pressing part 312.

### NUMERICAL REFERENCES

10, 110, 210, 310, 410, 510, 610 . . . Pressing device
11, 111, 211, 311, 411, 611 . . . Press plate
12, 112, 212, 312, 412, 612 . . . Pressing part
13 . . . Hard member
130_1, 130_2 . . . Taper part
14, 15 . . . Resilient member
20 . . . Mounting table
30 . . . Mounting substrate
31_1, 31_2 . . . Conductive pattern
32 . . . Mounting support substrate
40 . . . Element array
40a, 40b, 40c . . . Element
41_1, 41_2 . . . Electrode
50_1, 50_2 . . . Clamping member
51_1, 51_2 . . . Clamping slant part
60 . . . Transferring machine
61 . . . Stamp tool
70 . . . Supply table
80 . . . Supply substrate
81 . . . Substrate main body
82 . . . Adhesive layer
91 . . . Control unit
92 . . . Pressure control system
93 . . . Driving system
94 . . . Heating system
95 . . . Temperature control system

1. An element array pressing device comprising a press plate including a pressing part applying pressure to an element array having a plurality of elements provided on a mounting substrate, wherein
the pressing part comprises a hard member in a plate shape having a surface with a higher surface flatness than a surface of the press plate.

2. The element array pressing device according to claim 1, wherein the hard member is provided on the surface of the press plate.

3. The element array pressing device according to claim 2, wherein the pressing part comprises a resilient member in a plate shape, and
the resilient member is provided on the surface of the hard member.

4. The element array pressing device according to claim 1, wherein
the pressing part comprises a resilient member in a plate shape,
the resilient member is provided on the surface of the pressing plate, and
the hard member is provided on a surface of the resilient member.

5. The element array pressing device according to claim 4, wherein the hard member comprises one or more hard members and the resilient member comprises one or more resilient members, and
the one or more hard members and the one or more resilient members are stacked in an alternating manner on the surface of the pressing plate.

6. The element array pressing device according to claim 1, wherein a first water repelling layer, obtained by carrying out a water repellant treatment, is formed on the surface of the hard member.

7. The element array pressing device according to claim 3, wherein a second water repelling layer, obtained by carrying out a water repellant treatment, is formed on a surface of the resilient member.

8. The element array pressing device according to claim 7, wherein a first water repelling layer, obtained by carrying out a water repellant treatment, is formed on the surface of the hard member,
a thickness of the first water repelling layer is thinner than a thickness of the hard member, and a thickness of the second water repelling layer is thinner than a thickness of the resilient member.

9. The element array pressing device according claim 1, wherein the hard member is provided in a detachable manner with the press plate.

10. The element array pressing device according to claim 9, wherein the hard member is fixed to the press plate with a clamping member.

11. An element array manufacturing apparatus comprising the element array pressing device according to claim 1.

12. The element array manufacturing apparatus according to claim 11 further comprising
a mounting table on which the mounting substrate is placed,
a supply table on which a supply substrate having a plurality of elements is placed, and
a transferring machine which moves to the supply table and picks up the plurality of elements from the supply substrate and also moves to the mounting table and transfers the plurality of elements picked up from the supply substrate to the mounting substrate; in which
the press plate applies pressure to the element array having the plurality of elements transferred to the mounting substrate with the transferring machine.

13. A method of producing an element array including steps of
preparing a mounting substrate on which a plurality of elements is placed, and
applying pressure to the plurality of elements placed on the mounting substrate using a pressing device provided with a hard member in a plate shape having a surface with a higher surface flatness than a surface of a press plate.

14. The method of producing the element array according to claim 13, wherein the plurality of elements is connecting to the mounting substrate by pressing the plurality of elements towards a conductive bonding material provided on the mounting substrate.

15. An element array pressing device comprising a press plate including a pressing part which applies pressure to an element array having a plurality of elements placed on the mounting substrate, wherein
the pressing part includes a resilient member in a plate shape, and
a thickness of the resilient member is within a range of 0.5 to 2.0 times of a thickness of an element of the plurality of elements.

16. The element array pressing device according to claim 15, wherein the resilient member is provided on a surface of the press plate.

17. The element array pressing device according to claim 16, wherein
the pressing part comprises a hard member in a plate shape having a surface with a higher surface flatness than a surface of the press plate,
the hard member is provided on a surface of the resilient member, and
an another resilient member is provided on the surface of the hard member.

18. The element array pressing device according to claim 15, wherein
the pressing part comprises a hard member in a plate shape having a surface with a higher surface flatness than a surface of the press plate,
the hard member is provided on the surface of the press plate,
the resilient member is provided on the surface of the hard member.

19. The element array pressing device according to claim 17, wherein
the hard member comprises one or more hard members and the resilient member comprises one or more resilient members, and
the one or more hard members and the one or more resilient members are stacked in an alternating manner on the surface of the press plate.

20. The element array pressing device according to claim 15, wherein a water repelling layer, obtained by carrying out a water repellant treatment, is formed on the surface of the resilient member.

21. The element array pressing device according to claim 20, wherein a thickness of the water repelling layer is thinner than a thickness of the resilient member.

22. The element array pressing device according claim 15, wherein a thickness of an element of the plurality of elements is 50 μm or less.

23. An element array manufacturing apparatus comprising the element array pressing device according to claim 15.

24. The element array manufacturing apparatus according to claim 23 further comprising,
a mounting table on which a mounting substrate is placed,
a supply table on which a supply substrate having a plurality of elements is placed, and
a transferring machine which moves to the supply table and picks up the plurality of elements from the supply substrate and also moves to the mounting table and transfers the plurality of elements picked up from the supply table to the mounting substrate, in which
the press plate applies pressure to the element array having the plurality of elements transferred to the mounting substrate with the transferring machine.

25. A method of producing an element array including steps of
preparing a mounting substrate on which a plurality of elements is placed,
applying pressure to the plurality of elements placed on the mounting substrate with a pressing device provided with a resilient member in a plate shape having a thickness of 0.5 to 2.0 times of a thickness of an element of the plurality of elements.

26. The method of producing the element array according to claim 25 wherein the plurality of elements is connecting to the mounting substrate by pressing the plurality of elements towards a conductive bonding material provided on the mounting substrate.
